(19) United States
(12) Patent Application Publication
(10) Pub. No.: US 2025/0349551 A1
(43) Pub. Date: Nov. 13, 2025

(54) POLISHING LIQUID FOR CMP, POLISHING LIQUID SET FOR CMP, AND POLISHING METHOD

(71) Applicant: Resonac Corporation, Tokyo (JP)

(72) Inventors: Yuki SENBA, Tokyo (JP); Keita ARAKAWA, Tokyo (JP); Yucheng WANG, Tokyo (JP)

(21) Appl. No.: 18/861,003

(22) PCT Filed: Jan. 26, 2024
(86) PCT No.: PCT/JP2024/002500

§ 371 Date: Oct. 28, 2024

(30) Foreign Application Priority Data
Feb. 1, 2023 (WO) PCT/JP2023/003261

(51) Int. Cl. H01L 21/3105; B24B 37/04; C09K 3/14

(52) U.S. Cl. CPC H01L 21/31053; B24B 37/044; C09K 3/1463

(57) ABSTRACT

A polishing liquid for CMP includes abrasive grains, an additive A, a cationic polymer, and water, in which the additive A contains a compound having an ethylenediamine structure bonded to a hydroxyalkyl group or an alkoxide group. A polishing liquid set for CMP includes a first liquid and a second liquid, in which the components of the polishing liquid for CMP are separately stored in the first liquid and the second liquid, the first liquid contains the abrasive grains and water, and the second liquid contains the additive A, the cationic polymer, and water. A polishing method includes a step of polishing a surface to be polished using the polishing liquid for CMP.

### TECHNICAL FIELD

The present disclosure relates to a polishing liquid for CMP, a polishing liquid set for CMP, and a polishing method.

### BACKGROUND ART

In recent years, processing techniques for achieving higher density and finer features have become increasingly important in the process of manufacturing electronic devices. A chemical mechanical polishing (CMP) technique, which is one of the processing techniques, is an essential technique for the formation of shallow trench isolation (STI), planarization of pre-metal insulating material or interlayer insulating material, the formation of a plug or buried metal wiring, and the like in the process of manufacturing electronic devices. As a polishing liquid for CMP used for CMP, a polishing liquid for CMP which contains abrasive grains containing a cerium oxide is known (for example, refer to the following Patent Literatures 1 and 2).

### CITATION LIST

### Patent Literature

Patent Literature 1: Japanese Unexamined Patent Publication No. H10-106994
Patent Literature 2: Japanese Unexamined Patent Publication No. H08-022970

### SUMMARY OF INVENTION

### Technical Problem

In a CMP process, a stopper (a polishing stopping member; a member including a stopper) may be used as one of the methods for stopping polishing at a predetermined position. In one example of a CMP process using a stopper, a base having a substrate with a concave-convex pattern, a stopper placed on the convex portion of the substrate, and an insulating material (for example, silicon oxide and silicon nitride) placed on the substrate and the stopper so as to fill the concave portion is polished to remove an unnecessary portion of the insulating material. Since it is difficult to control the amount of the insulating material that is polished (the amount of the insulating material that is removed), this configuration allows the degree of polishing to be controlled by polishing the insulating material until the stopper is exposed. In such polishing, it is necessary to suppress the polishing rate of the stopper while polishing the insulating material at a high polishing rate. In recent years, the use of polysilicon and amorphous silicon as a stopper has increased, and it is therefore necessary to suppress the polishing rate of, for example, polysilicon and amorphous silicon.

The present disclosure has been made in consideration of the above circumstances, and an object of the present disclosure is to provide a polishing liquid that can suppress the polishing rate of polysilicon and amorphous silicon while polishing an insulating material at a high polishing rate. An object of the present disclosure is to provide a polishing liquid set for obtaining the polishing liquid. An object of the present disclosure is to provide a polishing method using the polishing liquid or the polishing liquid set.

### Solution to Problem

The present disclosure relates in some aspects to the following [1] to and the like.
[1] A polishing liquid for CMP, containing: abrasive grains; an additive A; a cationic polymer; and water, in which the additive A contains a compound having an ethylenediamine structure bonded to a hydroxyalkyl group or an alkoxide group.
[2] The polishing liquid for CMP according to [1], in which the abrasive grains contain at least one selected from the group consisting of cerium hydroxide, ceria, silica, and alumina.
[3] The polishing liquid for CMP according to [1] or [2], in which the abrasive grains contain cerium hydroxide.
[4] The polishing liquid for CMP according to any one of [1] to [3], in which the additive A contains 2,2′,2″,2′″-ethylenedinitrilotetraethanol.
[5] The polishing liquid for CMP according to any one of [1] to [4], in which the additive A contains 1,1′,1″,1′″-ethylenedinitrilotetra-2-propanol.
[6] The polishing liquid for CMP according to any one of [1] to [5], in which a content of the additive A is 0.001 to 5 mass %.
[7] The polishing liquid for CMP according to any one of [1] to [6], in which the cationic polymer includes a polymer having a quaternary ammonium salt structure or a polymer having an amino group.
[8] The polishing liquid for CMP according to any one of [1] to [7], in which a content of the cationic polymer is 2 to 20 parts by mass with respect to 100 parts by mass of the additive A.
[9] The polishing liquid for CMP according to any one of [1] to [8], further containing polyether.
[10] The polishing liquid for CMP according to any one of [1] to [9], in which pH is 4.0 to 10.0.
[11] The polishing liquid for CMP according to any one of [1] to [10], in which pH is higher than 6.0 and lower than 9.0.
[12] The polishing liquid for CMP according to any one of [1] to [11] is used for polishing a surface to be polished containing silicon oxide, silicon nitride, polysilicon, and amorphous silicon.
[13] A polishing liquid set for CMP, including: a first liquid; and a second liquid, in which components of the polishing liquid for CMP according to any one of [1] to [12] are separately stored in the first liquid and the second liquid, the first liquid contains the abrasive grains and water, and the second liquid contains the additive A, the cationic polymer, and water.
[14] A polishing method including a step of polishing a surface to be polished by using the polishing liquid for CMP according to any one of [1] to [12].
[15] The polishing method according to [14], in which the surface to be polished contains silicon oxide, silicon nitride, polysilicon, and amorphous silicon.
[16] A polishing method including a step of polishing a surface to be polished by using a polishing liquid for CMP obtained by mixing the first liquid and the second liquid of the polishing liquid set for CMP according to [13].
[17] The polishing method according to [16], in which the surface to be polished contains silicon oxide, silicon nitride, polysilicon, and amorphous silicon.

### Advantageous Effects of Invention

According to an aspect of the present disclosure, a polishing liquid that can suppress the polishing rate of a stopper while polishing an insulating material at a high polishing rate can be provided. According to another aspect of the present disclosure, a polishing liquid set for obtaining the polishing liquid can be provided. According to still another aspect of the present disclosure, a polishing method using the polishing liquid or the polishing liquid set can be provided.

### BRIEF DESCRIPTION OF DRAWINGS

FIG. 1 is a schematic cross-sectional view illustrating a polishing step when forming an STI structure of a semiconductor.

### DESCRIPTION OF EMBODIMENTS

Hereinafter, embodiments of the present disclosure will be described in detail.

In the present specification, a numerical range indicated using “to” indicates a range that includes the numerical values before and after “to” as the minimum value and maximum value, respectively. The numerical range “A or more” means A and a range exceeding A. The numerical range “A or less” means A and a range less than A. In the numerical ranges described in the present specification in stages, the upper limit or lower limit of the numerical range of one stage can be arbitrarily combined with the upper limit or lower limit of the numerical range of another stage. In a numerical range described in the present specification, the upper or lower limit of the numerical range may be replaced with values shown in Examples. “A or B” may include either A or B, or may include both. Unless otherwise specified, the materials exemplified in the present specification can be used singly or in combination of two or more. In a case where a plurality of substances corresponding to each component are present in a composition, the content of each component in the composition refers to the total amount of the plurality of substances present in the composition, unless otherwise specified. The term “layer” or “film” encompasses a structure having a shape formed on a part of a surface as well as a structure having a shape formed over the entire surface when observed in a plan view. The term “step” includes not only an independent step but also a case that cannot be clearly distinguished from other steps, as long as the intended effect of the step is achieved.

### <Polishing Liquid for CMP>

A polishing liquid for CMP of the present embodiment is a polishing liquid for CMP (hereinafter, simply referred to as “polishing liquid” in some cases) that contains abrasive grains, an additive A, a cationic polymer, and water. The additive A contains a compound having an ethylenediamine structure bonded to a hydroxyalkyl group or an alkoxide group.

According to the polishing liquid for CMP of the present embodiment, it is possible to suppress the polishing rate of polysilicon and amorphous silicon while polishing an insulating material at a high polishing rate.

According to the polishing liquid for CMP of the present embodiment, it is possible to polish, for example, silicon oxide at a high polishing rate, and, in the evaluation method described in Examples described later, a polishing rate of silicon oxide of, for example, 120 nm/min or more, 140 nm/min or more, 160 nm/min or more, 180 nm/min or more, 200 nm/min or more, 220 nm/min or more, 230 nm/min or more, 240 nm/min or more, 250 nm/min or more, 260 nm/min or more, 270 nm/min or more, or 280 nm/min or more can be obtained.

According to the polishing liquid for CMP of the present embodiment, it is possible to polish, for example, silicon nitride at a high polishing rate, and, in the evaluation method described in Examples described later, a polishing rate of silicon nitride of, for example, 30 nm/min or more, 40 nm/min or more, 50 nm/min or more, 60 nm/min or more, 70 nm/min or more, or 80 nm/min or more can be obtained.

According to the polishing liquid for CMP of the present embodiment, it is possible to suppress the polishing rate of, for example, polysilicon, and, in the evaluation method described in Examples described later, a polishing rate of polysilicon of, for example, 60 nm/min or less, 50 nm/min or less, 40 nm/min or less, 30 nm/min or less, 20 nm/min or less, 10 nm/min or less, 5 nm/min or less, 3 nm/min or less, or 2 nm/min or less can be obtained.

According to the polishing liquid for CMP of the present embodiment, it is possible to suppress the polishing rate of, for example, amorphous silicon, and, in the evaluation method described in Examples described later, a polishing rate of amorphous silicon of, for example, 5 nm/min or less, 4 nm/min or less, 3 nm/min or less, 2 nm/min or less, 1.5 nm/min or less, 1 nm/min or less, or 0.5 nm/min or less can be obtained.

The factors that bring about these effects are not entirely clear, but are presumed to be as follows. However, the factors are not limited to the following contents.

That is, since the polishing liquid for CMP of the present embodiment contains the cationic polymer, the cationic polymer is adsorbed to the polysilicon and amorphous silicon. This suppresses the polishing of the polysilicon and amorphous silicon by the abrasive grains, thereby achieving the suppression of the polishing rate of polysilicon and amorphous silicon. In addition, although the additive A tends to have high affinities with all of the insulating material (silicon oxide, silicon nitride, or the like), polysilicon, and amorphous silicon, since the cationic polymer protects the polysilicon and amorphous silicon, the ethylenediamine structure of the additive A, which is contained in the polishing liquid for CMP of the present embodiment, is selectively adsorbed to the insulating material. This allows the hydroxyalkyl group or the alkoxide group of the additive A to be exposed to the surface and the insulating material to become hydrophilic, thus increasing the affinity with the abrasive grains, by which the polishing can be performed easily, and a high polishing rate for the insulating material can be achieved.

### (Abrasive Grains)

The polishing liquid for CMP of the present embodiment contains abrasive grains. From the viewpoint of polishing the insulating material at a higher polishing rate, the abrasive grains may contain an inorganic compound, may contain at least one selected from the group consisting of a hydroxide of a metal element (for example, cerium hydroxide), a cerium oxide (for example, ceria (cerium (IV) oxide)), silica, alumina, zirconia, and yttria, may contain at least one selected from the group consisting of cerium hydroxide, ceria, silica, and alumina, and may contain cerium hydroxide.

The hydroxide of a metal element may be a hydroxide of a tetravalent metal element. The “hydroxide of a tetravalent metal element” is a compound containing a tetravalent metal (M⁴⁺) and at least one hydroxide ion (OH⁻). The hydroxide of a tetravalent metal element may contain an anion other than the hydroxide ion (for example, a nitrate ion NO₃⁻ and a sulfate ion SO₄²⁻). For example, the hydroxide of a tetravalent metal element may contain an anion (for example, a nitrate ion NO₃⁻ and a sulfate ion SO₄²⁻) bonded to the tetravalent metal element. The hydroxide of a tetravalent metal element can be prepared by causing a reaction between a salt of a tetravalent metal element (metal salt) and an alkali source (base).

The abrasive grains may contain cerium hydroxide (hydroxide of cerium) from the viewpoint of polishing the insulating material at a higher polishing rate and from the viewpoint of further suppressing the polishing rate of polysilicon and amorphous silicon. Cerium hydroxide can be prepared by causing a reaction between a cerium salt and an alkali source (base). Cerium hydroxide may be prepared by mixing a cerium salt with an alkaline solution (for example, an aqueous alkaline solution). By doing so, it is possible to obtain particles with extremely fine particle size, by which it is easy to obtain an excellent effect of reducing polishing flaws. Cerium hydroxide can be obtained by mixing a cerium salt solution (for example, an aqueous cerium salt solution) with an alkaline solution. Examples of the cerium salt include Ce(NO₃)₄, Ce(SO₄)₂, Ce(NH₄)₂(NO₃)₆, and Ce(NH₄)₄(SO₄)₄.

In a case where cerium hydroxide is used as the hydroxide of tetravalent cerium, it is considered that particles containing Ce(OH)ₐX_{b} (in the formula, a+b×c=4) consisting of tetravalent cerium (Ce⁴⁺), 1 to 3 hydroxide ions (OH⁻), and 1 to 3 anions (X^{c-}) are produced (note that such particles are also cerium hydroxide), depending on the production conditions of cerium hydroxide. It is considered that, in Ce(OH)ₐX_{b}, the reactivity of the hydroxide ions is enhanced by the action of the electron-withdrawing anions (X^{c-}), and the polishing rate increases as the abundance of Ce(OH)ₐX_{b} increases. Examples of the anion (X^{c-}) include NO₃⁻ and SO₄²⁻. It is considered that the particles containing cerium hydroxide can include not only Ce(OH)ₐX_{b} but also Ce(OH)₄, CeO₂, and the like.

The inclusion of Ce(OH)ₐX_{b} in the particles containing cerium hydroxide can be confirmed by thoroughly washing the particles with pure water and then detecting a peak corresponding to the anion (X^{c-}) using the Fourier transform Infra Red Spectrometer Attenuated Total Reflection method (FT-IR ATR method). The presence of the anion (X^{c-}) can also be confirmed by the X-ray Photoelectron Spectroscopy (XPS method).

In a case where the abrasive grains contain cerium hydroxide, the lower limit of the cerium hydroxide content may be, based on the entire abrasive grains (the entire abrasive grains contained in the polishing liquid for CMP; the same applies below), 50 mass % or more, more than 50 mass %, 60 mass % or more, 70 mass % or more, 80 mass % or more, 90 mass % or more, 95 mass % or more, or 100 mass % (an aspect substantially consisting of cerium hydroxide), from the viewpoint of polishing the insulating material at a higher polishing rate and from the viewpoint of further suppressing the polishing rate of polysilicon and amorphous silicon.

The lower limit of the average particle size of the abrasive grains in the polishing liquid for CMP or a slurry in a polishing liquid set for CMP to be described later may be 1 nm or more, 2 nm or more, 3 nm or more, 4 nm or more, 5 nm or more, more than 5 nm, 6 nm or more, 7 nm or more, 7.5 nm or more, or 8 nm or more, from the viewpoint of polishing the insulating material at a higher polishing rate. The upper limit of the average particle size of the abrasive grains may be 200 nm or less, 150 nm or less, 100 nm or less, 70 nm or less, 60 nm or less, 50 nm or less, 40 nm or less, 30 nm or less, 28 nm or less, 26 nm or less, 25 nm or less, 20 nm or less, 15 nm or less, 12 nm or less, 11 nm or less, 10 nm or less, less than 10 nm, 9 nm or less, 8.5 nm or less, or 8 nm or less, from the viewpoint of easily suppressing scratches on the surface to be polished. The lower limit of the average particle size of the abrasive grains may be 10 nm or more, 15 nm or more, 18 nm or more, 20 nm or more, 22 nm or more, 24 nm or more, or 25 nm or more. From these viewpoints, the average particle size of the abrasive grains may be 1 to 200 nm, 1 to 150 nm, or 1 to 60 nm.

The “average particle size” of the abrasive grains refers to the average secondary particle size of the abrasive grains. For example, the average particle size of the abrasive grains is the volume-average particle size, and can be measured in the polishing liquid for CMP or the slurry in the polishing liquid set for CMP to be described later using an optical diffraction/scattering particle size distribution meter (for example, trade name: DelsaMax PRO manufactured by Beckman Coulter, Inc., or trade name: Zetasizer 3000HSA manufactured by Malvern Instruments Ltd.).

The content of the abrasive grains may be within the following ranges based on the total mass of the polishing liquid for CMP. The lower limit of the content of the abrasive grains may be 0.001 mass % or more, 0.005 mass % or more, 0.01 mass % or more, 0.02 mass % or more, 0.03 mass % or more, 0.035 mass % or more, 0.04 mass % or more, 0.045 mass % or more, or 0.05 mass % or more, from the viewpoint of polishing the insulating material at a higher polishing rate. The upper limit of the content of the abrasive grains may be 20 mass % or less, 15 mass % or less, 10 mass % or less, 5 mass % or less, 1 mass % or less, 0.5 mass % or less, 0.1 mass % or less, 0.09 mass % or less, 0.08 mass % or less, 0.07 mass % or less, 0.06 mass % or less, or 0.05 mass % or less, from the viewpoint of further suppressing the polishing rate of polysilicon and amorphous silicon, and the viewpoint of easily obtaining excellent dispersion stability of the abrasive grains. From these viewpoints, the content of the abrasive grains may be 0.001 to 20 mass % or 0.01 to 10 mass %.

### (Additive)

### [Additive A]

The polishing liquid for CMP of the present embodiment contains an additive A. The additive A contains a compound having an ethylenediamine structure bonded to a hydroxyalkyl group or an alkoxide group.

The additive A has at least one hydroxyalkyl group or alkoxide group bonded to the ethylenediamine structure. A hydroxyalkyl group refers to an alkyl group substituted with a hydroxy group. An alkoxide group refers to a functional group in which the hydrogen atom of the hydroxy group in the hydroxyalkyl group is substituted with a metal atom (for example, a sodium atom). In a case where the additive A has a plurality of hydroxyalkyl groups, some of the hydroxyalkyl groups among the plurality of hydroxyalkyl groups may be alkoxide groups in which the hydrogen atom of the hydroxy group is substituted with a metal atom (for example, a sodium atom). The hydroxyalkyl group or alkoxide group may be directly bonded to the nitrogen atom of the ethylenediamine structure. In a case where the additive A has a plurality of hydroxyalkyl groups or alkoxide groups, the additive A may be a compound having an ethylenediamine structure bonded to the hydroxyalkyl groups or alkoxide groups and having two or more nitrogen atoms bonded to the hydroxyalkyl groups or alkoxide groups. The hydroxyalkyl group may or may not have a substituent other than the hydroxy group. The alkoxide group may or may not further have a substituent.

The number of carbon atoms of the alkyl group in the hydroxyalkyl group or alkoxide group may be within the following ranges, from the viewpoint of polishing the insulating material at a higher polishing rate and the viewpoint of further suppressing the polishing rate of polysilicon and amorphous silicon. The number of carbon atoms of the alkyl group in the hydroxyalkyl group or alkoxide group may be 10 or less, 8 or less, 6 or less, 5 or less, 4 or less, or 3 or less. The number of carbon atoms of the alkyl group in the hydroxyalkyl group or alkoxide group may be 1 or more, 2 or more, or 3 or more. From these viewpoints, the number of carbon atoms of the alkyl group in the hydroxyalkyl group or alkoxide group may be 1 to 10 or 1 to 5.

The number of hydroxy groups in the hydroxyalkyl group may be 1 or more. The number of hydroxy groups in the hydroxyalkyl group may be 10 or less, 8 or less, 6 or less, 4 or less, 3 or less, or 2 or less, from the viewpoint of polishing the insulating material at a higher polishing rate and the viewpoint of further suppressing the polishing rate of polysilicon and amorphous silicon.

The total number of the hydroxyalkyl group and the alkoxide group in the additive A may be within the following ranges, from the viewpoint of polishing the insulating material at a higher polishing rate and the viewpoint of further suppressing the polishing rate of polysilicon and amorphous silicon. The total number of the hydroxyalkyl group and the alkoxide group in the additive A may be 1 or more, 2 or more, 3 or more, or 4 or more. The total number of the hydroxyalkyl group and the alkoxide group in the additive A may be 10 or less, 8 or less, 6 or less, 5 or less, or 4 or less.

The additive A may be a compound having a nitrogen atom to which two hydroxyalkyl groups or alkoxide groups are bonded or may be a compound having two nitrogen atoms to which two hydroxyalkyl groups or alkoxide groups are bonded, from the viewpoint of polishing the insulating material at a higher polishing rate and the viewpoint of further suppressing the polishing rate of polysilicon and amorphous silicon.

The number of ethylenediamine structures in one molecule of the additive A may be 1 to 3, 1 to 2, or 1, from the viewpoint of polishing the insulating material at a higher polishing rate and the viewpoint of further suppressing the polishing rate of polysilicon and amorphous silicon.

The additive A may contain a compound represented by the following General Formula (1), from the viewpoint of polishing the insulating material at a higher polishing rate and the viewpoint of further suppressing the polishing rate of polysilicon and amorphous silicon.

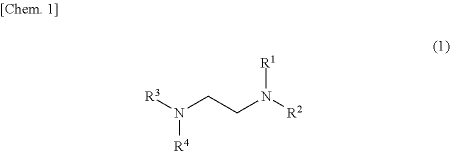

[In the formula, R¹, R², R³, and R⁴ each independently represent a hydrogen atom or an organic group, and at least one of R¹, R², R³, and R⁴ is a hydroxyalkyl group or an alkoxide group]

The organic group may be a substituted or unsubstituted alkyl group, or may be a hydroxyalkyl group or an alkoxide group. Examples of the substituent of the alkyl group include a carboxy group, an amino group, a sulfo group, and a nitro group. The number of carbon atoms of the alkyl group may be 10 or less, 8 or less, 6 or less, 5 or less, 4 or less, or 3 or less, and may be 1 or more, 2 or more, or 3 or more, from the viewpoint of polishing the insulating material at a higher polishing rate and the viewpoint of further suppressing the polishing rate of polysilicon and amorphous silicon.

Examples of the additive A include 1,1′,1″,1″-ethylenedinitrilotetra-2-propanol, 2,2′,2″,2′″-ethylenedinitrilotetraethanol, N-(2-hydroxypropyl)ethylenediamine, and ethylenediaminetetrapolyoxyalkylene (ethylenediaminetetrapolyoxyethylene, ethylenediaminepolyoxypropylene, or the like). From the viewpoint of polishing the insulating material at a higher polishing rate and the viewpoint of further suppressing the polishing rate of polysilicon and amorphous silicon, the additive A may contain at least one selected from the group consisting of 1,1′,1″,1″-ethylenedinitrilotetra-2-propanol, 2,2′,2″,2′″-ethylenedinitrilotetraethanol, N-(2-hydroxypropyl)ethylenediamine, and polyoxyalkylethylenediamine, may contain at least one selected from the group consisting of 1,1′,1″,1′″-ethylenedinitrilotetra-2-propanol and 2,2′,2″,2′″-ethylenedinitrilotetraethanolethylenedinitrilotetraethanol, may contain 1,1′,1″,1″-ethylenedinitrilotetra-2-propanol, or may contain 2,2′,2″,2′″-ethylenedinitrilotetraethanolethylenedinitrilotetraethanol. The additive A may not contain ethylenediaminetetrapolyoxyalkylene.

The content of the additive A may be within the following ranges, from the viewpoint of polishing the insulating material at a higher polishing rate and the viewpoint of further suppressing the polishing rate of polysilicon and amorphous silicon. The content of the additive A may be 100 or more, 120 or more, 140 or more, 160 or more, 180 or more, 200 or more, 220 or more, 230 or more, 240 or more, 250 or more, 260 or more, 270 or more, 280 or more, or 290 or more. The content of the additive A may be 1000 or less, less than 1000, 900 or less, 800 or less, 700 or less, 600 or less, 500 or less, 400 or less, 380 or less, 360 or less, 350 or less, 340 or less, 330 or less, 320 or less, 310 or less, 300 or less, or less than 300. From these viewpoints, the content of the additive A may be 100 to 1000, 160 to 500, or 200 to 350.

The content of the additive A or the content of the additive A may be within the following ranges based on the total mass of the polishing liquid for CMP, from the viewpoint of polishing the insulating material at a higher polishing rate and the viewpoint of further suppressing the polishing rate of polysilicon and amorphous silicon. The content of the additive A or the content of the additive A may be 0.001 mass % or more, 0.003 mass % or more, 0.005 mass % or more, 0.01 mass % or more, more than 0.01 mass %, 0.015 mass % or more, 0.02 mass % or more, more than 0.02 mass %, 0.025 mass % or more, 0.03 mass % or more, more than 0.03 mass %, 0.035 mass % or more, or 0.04 mass % or more. The content of the additive A or the content of the additive A may be 5 mass % or less, 3 mass % or less, 1 mass % or less, 0.5 mass % or less, 0.3 mass % or less, 0.2 mass % or less, 0.15 mass % or less, 0.12 mass % or less, 0.1 mass % or less, less than 0.1 mass %, 0.09 mass % or less, 0.08 mass % or less, 0.07 mass % or less, 0.06 mass % or less, 0.055 mass % or less, 0.05 mass % or less, less than 0.05 mass %, 0.045 mass % or less, or 0.04 mass % or less. From these viewpoints, the content of the additive A or the content of the additive A may be 0.001 to 5 mass %, 0.005 to 1 mass %, 0.01 to 0.5 mass %, 0.02 to 0.2 mass %, or 0.02 to 0.12 mass %.

The content of the additive A or the content of the additive A may be within the following ranges with respect to 100 parts by mass of the abrasive grains, from the viewpoint of polishing the insulating material at a higher polishing rate and the viewpoint of further suppressing the polishing rate of polysilicon and amorphous silicon. The content of the additive A or the content of the additive A may be 1 parts by mass or more, 5 parts by mass or more, 10 parts by mass or more, 15 parts by mass or more, 20 parts by mass or more, 25 parts by mass or more, 30 parts by mass or more, 35 parts by mass or more, 40 parts by mass or more, 45 parts by mass or more, 50 parts by mass or more, 55 parts by mass or more, 60 parts by mass or more, 65 parts by mass or more, 70 parts by mass or more, 75 parts by mass or more, or 80 parts by mass or more. The content of the additive A or the content of the additive A may be 1000 parts by mass or less, 800 parts by mass or less, 600 parts by mass or less, 400 parts by mass or less, 350 parts by mass or less, 300 parts by mass or less, 240 parts by mass or less, 200 parts by mass or less, 190 parts by mass or less, 180 parts by mass or less, 170 parts by mass or less, 160 parts by mass or less, 150 parts by mass or less, 140 parts by mass or less, 130 parts by mass or less, 120 parts by mass or less, 110 parts by mass or less, 100 parts by mass or less, 90 parts by mass or less, or 80 parts by mass or less. From these viewpoints, the content of the additive A or the content of the additive A may be 1 to 1000 parts by mass, 10 to 600 parts by mass, 20 to 400 parts by mass, 40 to 240 parts by mass, or 20 to 160 parts by mass.

### [Cationic Polymer]

The polishing liquid for CMP of the present embodiment contains a cationic polymer. The “cationic polymer” is defined as a polymer that has a cationic group or a group that can be ionized into a cationic group in the main chain or on the side chain thereof. Examples of the cationic group include an amino group, an imino group, and a cyano group.

Examples of the cationic polymer include a polymer obtained by polymerizing at least one monomer component selected from the group consisting of allylamine, diallylamine, vinylamine, ethylenimine, and derivatives thereof (an allylamine polymer, a diallylamine polymer, a vinylamine polymer, or an ethyleneimine polymer); and a polysaccharide such as chitosan and a chitosan derivative. The cationic polymer may include a polymer having a quaternary ammonium salt structure or a polymer having an amino group.

An allylamine polymer is a polymer obtained by polymerizing allylamine or a derivative thereof. Examples of the allylamine derivative include alkoxycarbonylated allylamine, methylcarbonylated allylamine, aminocarbonylated allylamine, and urea-based allylamine.

A diallylamine polymer is a polymer obtained by polymerizing diallylamine or a derivative thereof. Examples of the diallylamine derivative include methyl diallylamine, diallyl dimethyl ammonium salt, diallyl methyl ethyl ammonium salt, acylated diallylamine, aminocarbonylated diallylamine, alkoxycarbonylated diallylamine, aminothiocarbonylated diallylamine, and hydroxyalkylated diallylamine. Examples of the ammonium salt include ammonium chloride and ammonium alkyl sulfate (for example, ammonium ethyl sulfate).

A vinylamine polymer is a polymer obtained by polymerizing vinylamine or a derivative thereof. Examples of the vinylamine derivative include alkylated vinylamine, amidated vinylamine, ethylene oxide-based vinylamine, propylene oxide-based vinylamine, alkoxylated vinylamine, carboxymethylated vinylamine, acylated vinylamine, and urea-based vinylamine.

An ethyleneimine polymer is a polymer obtained by polymerizing ethyleneimine or a derivative thereof. Examples of the ethyleneimine derivative include an aminoethylated acrylic polymer, alkylated ethyleneimine, urea-based ethyleneimine, and propylene oxide-based ethyleneimine.

The cationic polymer may have a structural unit derived from a monomer component other than the allylamine, diallylamine, vinylamine, ethylenimine and derivatives thereof. The cationic polymer may have, for example, a structural unit derived from acrylamide, dimethylacrylamide, diethylacrylamide, hydroxyethylacrylamide, acrylic acid, methyl acrylate, methacrylic acid, methyl methacrylate, 2-(dimethylamino)ethyl methacrylate, maleic acid, epichlorohydrin, or sulfur dioxide.

The cationic polymer may be a homopolymer of allylamine, diallylamine, vinylamine or ethyleneimine (polyallylamine, polydiallylamine, polyvinylamine, or polyethyleneimine), or may be a copolymer having structural units derived from allylamine, diallylamine, vinylamine, ethyleneimine, or derivatives thereof. In the copolymer, the structural units may be arranged in any order. For example, the copolymer can be in any of the following forms: (a) the form of a block copolymer in which each of the same structural units is consecutively arranged, (b) the form of a random copolymer in which structural units A and structural units B are arranged in no particular order, and (c) the form of an alternating copolymer in which the structural units A and the structural units B are alternately arranged.

The cationic polymer may be a copolymer obtained by polymerizing a composition containing acrylamide as the monomer component, from the viewpoint of polishing the insulating material at a higher polishing rate and the viewpoint of further suppressing the polishing rate of polysilicon and amorphous silicon. The cationic polymer may be a copolymer obtained by polymerizing a composition containing a diallyldimethylammonium salt and acrylamide as the monomer components, or a copolymer obtained by polymerizing a composition containing a diallylamine hydrochloride and acrylamide as the monomer components, from the viewpoint of polishing the insulating material at a higher polishing rate and the viewpoint of further suppressing the polishing rate of polysilicon and amorphous silicon. The cationic polymer may be a diallyldimethylammonium chloride-acrylamide copolymer or a diallylamine hydrochloride-acrylamide copolymer, from the viewpoint of polishing the insulating material at a higher polishing rate and the viewpoint of further suppressing the polishing rate of polysilicon and amorphous silicon.

The cationic polymer may be a copolymer obtained by polymerizing a composition containing epichlorohydrin as the monomer component, from the viewpoint of polishing the insulating material at a higher polishing rate and the viewpoint of further suppressing the polishing rate of polysilicon and amorphous silicon. The cationic polymer may be a polycondensate obtained by polycondensating a composition containing dimethylamine, ammonia, and epichlorohydrin as the monomer components, or a modified polymer obtained by modifying and polymerizing a composition containing methyldiallylamine hydrochloride and epichlorohydrin as the monomer components, from the viewpoint of polishing the insulating material at a higher polishing rate and the viewpoint of further suppressing the polishing rate of polysilicon and amorphous silicon. The cationic polymer may be a dimethylamine-ammonia-epichlorohydrin polycondensate or a methyldiallylamine hydrochloride-epichlorohydrin modified polymer, from the viewpoint of polishing the insulating material at a higher polishing rate and the viewpoint of further suppressing the polishing rate of polysilicon and amorphous silicon.

The cationic polymer may be a copolymer obtained by polymerizing a composition containing 2-(dimethylamino)ethyl methacrylate as the monomer component, may be a copolymer obtained by polymerizing a composition containing vinylpyrrolidone and 2-(dimethylamino)ethyl methacrylate as the monomer components, or may be vinylpyrrolidone-N,N-dimethylaminoethyl methacrylic acid copolymer diethyl sulfate, from the viewpoint of polishing the insulating material at a higher polishing rate and the viewpoint of further suppressing the polishing rate of polysilicon and amorphous silicon.

The cationic polymer may be an amine polymer such as an allylamine polymer, a diallylamine polymer, and a vinylamine polymer, or may be at least one selected from the group consisting of polyallylamine and diallyldimethylammonium chloride, from the viewpoint of polishing the insulating material at a higher polishing rate and the viewpoint of further suppressing the polishing rate of polysilicon and amorphous silicon. One type of the cationic polymer can be used singly, or two or more types of the cationic polymers can be used in combination, for the purpose of adjusting the polishing properties such as polishing selectivity and planeness.

The lower limit of the weight-average molecular weight of the cationic polymer may be 100 or more, 300 or more, 500 or more, 1000 or more, or 1500 or more, from the viewpoint of polishing the insulating material at a higher polishing rate and the viewpoint of further suppressing the polishing rate of polysilicon and amorphous silicon. The upper limit of the weight-average molecular weight of the cationic polymer may be 1000000 or less, 800000 or less, 600000 or less, 300000 or less, or 200000 or less, from the viewpoint of polishing the insulating material at a higher polishing rate and the viewpoint of further suppressing the polishing rate of polysilicon and amorphous silicon. From these viewpoints, the weight-average molecular weight of the cationic polymer may be 100 to 1000000 or 500 to 300000. The weight-average molecular weight of the cationic polymer can be measured by, for example, gel permeation chromatography (GPC) using a calibration curve of polystyrene standard under the following conditions.
Device used: Hitachi L-6000 type [manufactured by Hitachi, Ltd.]
Columns: Gelpack GL-R420+Gelpack GL-R430+Gelpack GL-R440 [product names, manufactured by Hitachi High-Tech Corporation, total of 3]
Eluent: Tetrahydrofuran
Measurement temperature: 40° C.
Flow rate: 1.75 mL/min
Detector: L-3300RI [manufactured by Hitachi, Ltd.]

The content of the cationic polymer may be within the following ranges based on the total mass of the polishing liquid for CMP, from the viewpoint of polishing the insulating material at a higher polishing rate and the viewpoint of further suppressing the polishing rate of polysilicon and amorphous silicon. The content of the cationic polymer may be 0.0001 mass % or more, 0.0005 mass % or more, 0.001 mass % or more, 0.0015 mass % or more, 0.002 mass % or more, 0.0025 mass % or more, or 0.003 mass % or more. The content of the cationic polymer may be 5 mass % or less, 1 mass % or less, 0.1 mass % or less, 0.05 mass % or less, 0.01 mass % or less, 0.008 mass % or less, 0.006 mass % or less, 0.005 mass % or less, 0.0045 mass % or less, 0.004 mass or less, or 0.003 mass % or less. From these viewpoints, the content of the cationic polymer may be 0.0001 to 5 mass %, 0.001 to 0.1 mass %, or 0.002 to 0.01 mass %.

The content of the cationic polymer may be within the following ranges with respect to 100 parts by mass of the abrasive grains, from the viewpoint of polishing the insulating material at a higher polishing rate and the viewpoint of further suppressing the polishing rate of polysilicon and amorphous silicon. The content of the cationic polymer may be more than 0 parts by mass, 0.1 parts by mass or more, 0.5 parts by mass or more, 0.8 parts by mass or more, 1 parts by mass or more, 1.5 parts by mass or more, 2 parts by mass or more, 2.5 parts by mass or more, 3 parts by mass or more, 3.5 parts by mass or more, 4 parts by mass or more, 4.5 parts by mass or more, 5 parts by mass or more, 5.5 parts by mass or more, or 6 parts by mass or more. The content of the cationic polymer may be 100 parts by mass or less, 50 parts by mass or less, 30 parts by mass or less, 20 parts by mass or less, 15 parts by mass or less, 12 parts by mass or less, 10 parts by mass or less, 9.5 parts by mass or less, 9 parts by mass or less, 8.5 parts by mass or less, 8 parts by mass or less, 7.5 parts by mass or less, 7 parts by mass or less, 6.5 parts by mass or less, or 6 parts by mass or less. From these viewpoints, the content of the cationic polymer may be more than 0 parts by mass and 100 parts by mass or less, 1 to 20 parts by mass, 2 to 15 parts by mass, or 2 to 10 parts by mass.

The content of the cationic polymer may be within the following ranges with respect to 100 parts by mass of the additive A, from the viewpoint of polishing the insulating material at a higher polishing rate and the viewpoint of further suppressing the polishing rate of polysilicon and amorphous silicon. The content of the cationic polymer may be more than 0 parts by mass, 0.1 parts by mass or more, 0.5 parts by mass or more, 0.8 parts by mass or more, 1 parts by mass or more, 1.5 parts by mass or more, 2 parts by mass or more, 2.5 parts by mass or more, 3 parts by mass or more, 3.5 parts by mass or more, 3.75 parts by mass or more, 4 parts by mass or more, 4.5 parts by mass or more, 5 parts by mass or more, 5.5 parts by mass or more, 6 parts by mass or more, 6.5 parts by mass or more, 7 parts by mass or more, or 7.5 parts by mass or more. The content of the cationic polymer may be 100 parts by mass or less, 50 parts by mass or less, 30 parts by mass or less, 20 parts by mass or less, 15 parts by mass or less, 12 parts by mass or less, 11.5 parts by mass or less, 11.25 or less, 11 parts by mass or less, 10.5 parts by mass or less, 10 parts by mass or less, 9.5 parts by mass or less, 9 parts by mass or less, 8.5 parts by mass or less, 8 parts by mass or less, or 7.5 parts by mass or less. From these viewpoints, the content of the cationic polymer may be more than 0 parts by mass and 100 parts by mass or less, 1 to 50 parts by mass, 2 to 20 parts by mass, or 3.5 to 11.5 parts by mass.

### (Water)

The water is not particularly limited, but may contain at least one selected from the group consisting of deionized water, ion exchanged water, and ultrapure water.

### (Other Additives)

The polishing liquid for CMP of the present embodiment may contain a component other than the abrasive grains, the additive A, the cationic polymer, and the water. Examples of such a component include polyether, a pH adjusting agent, an anticorrosive, a peroxide, an organic solvent, a surfactant, and a defoaming agent. The polishing liquid for CMP of the present embodiment may not contain at least one of these components.

### [Polyether]

The polishing liquid of the present embodiment may contain polyether, from the viewpoint of polishing the insulating material at a higher polishing rate and the viewpoint of further suppressing the polishing rate of polysilicon and amorphous silicon. Polyether is a compound that has two or more ether groups. The “ether group” in the polyether does not contain the “—O—” structure in a hydroxy group (hydroxyl group), a carboxy group, a carboxylate group, an ester group, a sulfo group, or a phosphate group.

Examples of the polyether include, polyglycerol, a polysaccharide, polyalkylene glycol, polyoxypropylene polyglyceryl ether, polyoxyethylene polyglyceryl ether, 1,4-di(2-hydroxyethoxy)benzene, 2,2-bis(4-polyoxyethyleneoxyphenyl)propane, 2,2-bis(4-polyoxypropyleneoxyphenyl)propane, ethylene glycol monophenyl ether, diethylene glycol monophenyl ether, polyoxyalkylene monophenyl ether, propylene glycol monophenyl ether, polyoxypropylene monomethyl phenyl ether, polyethylene glycol monomethyl ether, pentaerythritol polyoxyethylene ether, ethylene glycol monoallyl ether, polyoxyethylene monoallyl ether, and alkyl glucoside. The polyether may include polyglycerol, from the viewpoint of polishing the insulating material at a higher polishing rate and the viewpoint of further suppressing the polishing rate of polysilicon and amorphous silicon.

The polyether may include polyglycerol having the average degree of polymerization of glycerol within the following ranges, from the viewpoint of polishing the insulating material at a higher polishing rate and the viewpoint of further suppressing the polishing rate of polysilicon and amorphous silicon. The average degree of polymerization of glycerol may be 3 or more, 4 or more, 5 or more, 8 or more, or 10 or more. The average degree of polymerization of glycerol may be 100 or less, 80 or less, 60 or less, 50 or less, 40 or less, or 30 or less. From these viewpoints, the average degree of polymerization of glycerol may be 3 to 100 or 5 to 60.

The weight-average molecular weight of the polyether may be within the following ranges, from the viewpoint of polishing the insulating material at a higher polishing rate and the viewpoint of further suppressing the polishing rate of polysilicon and amorphous silicon. The weight-average molecular weight may be 250 or more, 300 or more, 350 or more, 400 or more, 450 or more, or 500 or more. The weight-average molecular weight of the polyether may be 5000 or less, 4000 or less, 3500 or less, 3000 or less, 2500 or less, or 2000 or less. From these viewpoints, the weight-average molecular weight may be 250 to 5000. The weight-average molecular weight of the polyether can be measure by the same method as that for measuring the weight-average molecular weight of the cationic polymer.

The content of the polyether may be within the following ranges based on the total mass of the polishing liquid for CMP, from the viewpoint of polishing the insulating material at a higher polishing rate and the viewpoint of further suppressing the polishing rate of polysilicon and amorphous silicon. The content of the polyether may be more than 0 mass %, 0.01 mass % or more, 0.05 mass % or more, 0.1 mass % or more, more than 0.1 mass %, 0.2 mass % or more, 0.3 mass % or more, 0.35 mass % or more, 0.4 mass % or more, 0.45 mass % or more, or 0.5 mass % or more. The content of the polyether may be 10 mass % or less, 8 mass % or less, 5 mass % or less, 3 mass % or less, 2 mass % or less, 1 mass % or less, less than 1 mass %, 0.8 mass % or less, 0.7 mass % or less, 0.65 mass % or less, 0.6 mass % or less, 0.55 mass % or less, or 0.5 mass % or less. From these viewpoints, the content of the polyether may be more than 0 mass % and 10 mass % or less or 0.1 to 3 mass %.

The content of the polyether may be within the following ranges with respect to 100 parts by mass of the abrasive grains, from the viewpoint of polishing the insulating material at a higher polishing rate and the viewpoint of further suppressing the polishing rate of polysilicon and amorphous silicon. The content of the polyether may be more than 0 parts by mass, 10 parts by mass or more, 50 parts by mass or more, 100 parts by mass or more, 150 parts by mass or more, 200 parts by mass or more, 250 parts by mass or more, 300 parts by mass or more, 350 parts by mass or more, 400 parts by mass or more, 450 parts by mass or more, 500 parts by mass or more, 550 parts by mass or more, 600 parts by mass or more, 650 parts by mass or more, 700 parts by mass or more, 750 parts by mass or more, 800 parts by mass or more, 850 parts by mass or more, 900 parts by mass or more, 950 parts by mass or more, or 1000 parts by mass or more. The content of the polyether may be 10000 parts by mass or less, 8000 parts by mass or less, 6000 parts by mass or less, 5000 parts by mass or less, 4000 parts by mass or less, 3000 parts by mass or less, 2000 parts by mass or less, 1900 parts by mass or less, 1800 parts by mass or less, 1700 parts by mass or less, 1600 parts by mass or less, 1500 parts by mass or less, 1400 parts by mass or less, 1300 parts by mass or less, 1200 parts by mass or less, 1100 parts by mass or less, or 1000 parts by mass or less. From these viewpoints, the content of the polyether may be more than 0 parts by mass and 10000 parts by mass or less or 300 to 1500 parts by mass.

The content of the polyether may be within the following ranges with respect to 100 parts by mass of the additive A, from the viewpoint of polishing the insulating material at a higher polishing rate and the viewpoint of further suppressing the polishing rate of polysilicon and amorphous silicon. The content of the polyether may be more than 0 parts by mass, 10 parts by mass or more, 50 parts by mass or more, 100 parts by mass or more, 200 parts by mass or more, 300 parts by mass or more, 350 parts by mass or more, 400 parts by mass or more, 450 parts by mass or more, 500 parts by mass or more, 550 parts by mass or more, 600 parts by mass or more, 650 parts by mass or more, 700 parts by mass or more, 750 parts by mass or more, 800 parts by mass or more, 850 parts by mass or more, 900 parts by mass or more, 950 parts by mass or more, 1000 parts by mass or more, 1100 parts by mass or more, 1200 parts by mass or more, or 1250 parts by mass or more. The content of the polyether may be 10000 parts by mass or less, 8000 parts by mass or less, 7000 parts by mass or less, 6500 parts by mass or less, 6000 parts by mass or less, 5500 parts by mass or less, 5000 parts by mass or less, 4500 parts by mass or less, 4000 parts by mass or less, 3500 parts by mass or less, 3000 parts by mass or less, 2500 parts by mass or less, 2000 parts by mass or less, 1800 parts by mass or less, 1600 parts by mass or less, 1400 parts by mass or less, 1300 parts by mass or less, or 1250 parts by mass or less. From these viewpoints, the content of the polyether may be more than 0 parts by mass and 10000 parts by mass or less or 500 to 5000 parts by mass.

### [pH Adjusting Agent]

Although the pH adjusting agent is not particularly limited, examples thereof include an acid component such as acetic acid, nitric acid, sulfuric acid, hydrochloric acid, phosphoric acid, and boric acid; and a base component such as sodium hydroxide, ammonia (for example, aqueous ammonia), potassium hydroxide, and calcium hydroxide. From the viewpoint of improving productivity, the polishing liquid for CMP may be prepared without using the pH adjusting agent.

Based on the total mass of the polishing liquid for CMP, the content of the acid component may be, for example, more than 0 mass %, 0.001 mass % or more, 0.005 mass % or more, 0.008 mass % or more, 0.01 mass % or more, 0.012 mass % or more, 0.014 mass % or more, or 0.016 mass % or more, and may be 5 mass % or less, 3 mass % or less, 1 mass % or less, 0.5 mass % or less, 0.1 mass % or less, 0.05 mass % or less, 0.03 mass % or less, 0.02 mass % or less, 0.018 mass % or less, or 0.016 mass % or less. The polishing liquid may or may not contain the acid component.

Based on the total mass of the polishing liquid for CMP, the content of the base component may be, for example, more than 0 mass %, 0.00001 mass % or more, 0.00005 mass % or more, 0.0001 mass % or more, 0.0005 mass % or more, 0.0008 mass % or more, 0.001 mass % or more, or 0.013 mass % or more, and may be 5 mass % or less, 3 mass % or less, 1 mass % or less, 0.5 mass % or less, 0.1 mass % or less, 0.05 mass % or less, 0.04 mass % or less, 0.031 mass % or less, 0.02 mass % or less, 0.015 mass % or less, or 0.013 mass % or less. The polishing liquid may or may not contain the base component.

(pH)

The pH of the polishing liquid for CMP of the present embodiment may be within the following ranges, from the viewpoint of polishing the insulating material at a higher polishing rate and the viewpoint of further suppressing the polishing rate of polysilicon and amorphous silicon. The pH may be 10.0 or less, less than 10.0, 9.5 or less, 9.0 or less, less than 9.0, 8.8 or less, 8.5 or less, 8.2 or less, 8.0 or less, less than 8.0, 7.9 or less, 7.8 or less, 7.7 or less, 7.6 or less, 7.5 or less, 7.4 or less, 7.3 or less, 7.2 or less, 7.1 or less, or 7.0 or less. The pH may be 4.0 or more, more than 4.0, 4.5 or more, 5.0 or more, more than 5.0, 5.2 or more, 5.5 or more, 5.7 or more, 6.0 or more, more than 6.0, 6.1 or more, 6.2 or more, 6.3 or more, 6.4 or more, 6.5 or more, 6.6 or more, 6.7 or more, 6.8 or more, 6.9 or more, or 7.0 or more. From these viewpoints, the pH may be 4.0 to 10.0, 5.0 to 9.0, 5.0 or more and less than 9.0, 5.5 to 8.5, 6.0 or more and less than 9.0, 6.0 to 8.0, more than 6.0 and less than 9.0, more than 6.0 and 8.0 or less, or 6.5 to 7.5. The pH can be measured by the method described in Examples.

### <Preparation Method and Usage of Polishing Liquid for CMP>

The polishing liquid for CMP of the present embodiment can be classified into (a) a standard type, (b) a concentrated type, and (c) a multi-liquid type (for example, a two-liquid type; polishing liquid set for CMP), and the preparation method and usage differ depending on the type. (a) The standard type is a polishing liquid for CMP that can be used as is without performing pretreatment such as dilution when polishing. (b) The concentrated type is a polishing liquid for CMP in which the components are concentrated compared to (a) the standard type by taking into consideration convenience in storage and transportation. (c) The multi-liquid type is a polishing liquid for CMP in which the components are in a state of being separated into multiple liquids (for example, separated into a first liquid containing certain components and a second liquid containing other components) during storage or transportation, and these liquids are mixed when used.
(a) The standard type can be obtained by dissolving or dispersing the abrasive grains and the additive in water, which is the main dispersion medium. The polishing liquid for CMP can be prepared using, for example, a stirrer, a homogenizer, an ultrasonic disperser, wet ball mill, or the like. A treatment of microparticulating the abrasive grains may be performed in the process of preparing the polishing liquid for CMP, so that the average particle size of the abrasive grains is within a desired range. The treatment of microparticulating the abrasive grains can be performed by a method using a settling classification method or a high pressure homogenizer. The settling classification method is a method including a step of forcibly settling a slurry containing the abrasive grains using a centrifuge and a step of removing only the supernatant liquid. On the other hand, the method using a high pressure homogenizer is a method in which the abrasive grains in a dispersion medium are collided with each other at a high pressure.
(b) The concentrated type is diluted with water to the desired content of the components immediately before use. After the dilution, stirring may be performed for any length of time until the liquid properties (pH, particle size of the abrasive grains, and the like) and polishing properties (polishing rate of silicon oxide, polishing selectivity ratio between silicon oxide and silicon nitride, and the like) comparable to those of (a) the standard type are obtained. In such (b) a concentrated type, the volume becomes smaller depending on the degree of concentration, and thus, the costs of storage and transportation can be reduced.

The concentration ratio may be 1.5-fold or more, 2-fold or more, 3-fold or more, or 5-fold or more. When the concentration ratio is 1.5-fold or more, advantages in terms of storage and transportation tend to be easily obtained, compared to a case where the concentration ratio is less than 1.5. The concentration ratio may be 40-fold or less, 20-fold or less, or 15-fold or less. When the concentration ratio is 40-fold or less, aggregation of the abrasive grains tends to be easily suppressed, compared to a case where the concentration ratio is more than 40-fold.
(c) The multi-liquid type is the advantageous in that each liquid (first liquid, second liquid, and the like) is appropriately separated, thus being able to avoid the aggregation of abrasive grains, compared to (b) the concentrated type. Here, the components contained in each liquid are arbitrary. (c) The multi-liquid type (polishing liquid set for CMP) is a polishing liquid set for CMP for obtaining the polishing liquid for CMP by mixing a first liquid (slurry) and a second liquid (additive liquid). In (c) the multi-liquid type, the components of the polishing liquid for CMP are separately stored in the first liquid and the second liquid, the first liquid contains the abrasive grains and water, and the second liquid contains at least one type of additive and water. In a first aspect of (c) the multi-liquid type, the first liquid contains the abrasive grains and water, and the second liquid contains the additive A, the cationic polymer, and water. In a second aspect of (c) the multi-liquid type, the first liquid contains the abrasive grains, one of the additive A and the cationic polymer, and water, and the second liquid contains the other one of the additive A and the cationic polymer and water. The first liquid and the second liquid may contain another component that is blended as necessary. In this case, in order to increase the dispersibility of the abrasive grains in the first liquid, an arbitrary acid component or base component may be added to the first liquid to adjust the pH.
(c) The multi-liquid type polishing liquid for CMP is useful in the case of combining components of which the polishing properties tend to deteriorate within a relatively short amount of time due to aggregation of the abrasive grains or the like when mixed together. From the viewpoint of reducing the costs for storage and transportation, at least one of the liquids (first liquid, second liquid, and the like) may be of a concentrated type. In this case, each liquid may be mixed with water when using the polishing liquid for CMP. The concentration ratio and pH of each liquid are arbitrarily determined, provided that the final mixture has polishing properties comparable to those of (a) the standard type polishing liquid for CMP.

### <Polishing Method>

A polishing method of the present embodiment may include a polishing step of polishing a surface to be polished using the above polishing liquid, or may include a polishing step of polishing a surface to be polished using a polishing liquid obtained by mixing the slurry and additive liquid in the above polishing liquid set.

The surface to be polished may contain a stopper. The surface to be polished may contain a stopper and an insulating material, or may contain a stopper, silicon oxide, and silicon nitride. The polishing method of the present embodiment may include, for example, a polishing step of polishing the surface to be polished using the above polishing liquid for CMP or a polishing liquid for CMP obtained by mixing the slurry and the additive liquid in the above polishing liquid set for CMP. According to the polishing method of the present embodiment, it is possible to suppress the polishing rate of the stopper while polishing the insulating material at a high polishing rate.

Examples of the insulating material include silicon oxide and silicon nitride. Examples of the stopper include polysilicon and amorphous silicon.

Examples of a method for preparing the insulating material and the stopper include CVD methods such as a low pressure CVD method, a subatmospheric pressure CVD method, and a plasma CVD method; and a spin-coating method in which a liquid raw material is applied onto a spinning substrate.

Each of the insulating material and the stopper may be a single material or multiple materials. When multiple materials are exposed on the surface to be polished, the materials can be considered as the insulating material and the stopper. The insulating material and the stopper may be in a form of a film, and may be a silicon oxide film, a silicon nitride film, a polysilicon film, an amorphous silicon film, or the like.

The polishing method of the present embodiment may be a polishing method for a base. The base may have, for example, a stopper (a member containing a stopper). The base may have, for example, a stopper and a member containing an insulating material. In the present embodiment, it is possible to stop the polishing of a base having a stopper containing a stopper (polysilicon, amorphous silicon, or the like) and a member containing an insulating material (silicon oxide, silicon nitride, or the like) at the stopper. Of the present embodiment, a polishing method for a base having an insulating material and a stopper can be provided, the polishing method including a polishing step of polishing a surface to be polished using the above polishing liquid for CMP or a polishing liquid for CMP obtained by mixing the slurry and the additive liquid in the above polishing liquid set for CMP. According to the polishing method of the present embodiment, it is possible to suppress the polishing rate of polysilicon and amorphous silicon while polishing an insulating material at a high polishing rate.

Examples of the base to be polished include a substrate, such as a substrate obtained by forming a member containing an insulating material and a stopper on a substrate used for manufacturing a semiconductor device (for example, a semiconductor substrate on which an STI pattern, a gate pattern, a wiring pattern, or the like is formed).

In the polishing step, for example, the above polishing liquid for CMP is supplied between the surface of the base to be polished and a polishing pad of a polishing surface plate in a state of pressing the surface to be polished onto the polishing pad and the surface to be polished is polished by moving the base and the polishing surface plate relative to each other. In the polishing step, for example, at least a portion of the insulating material in the surface to be polished is removed by polishing.

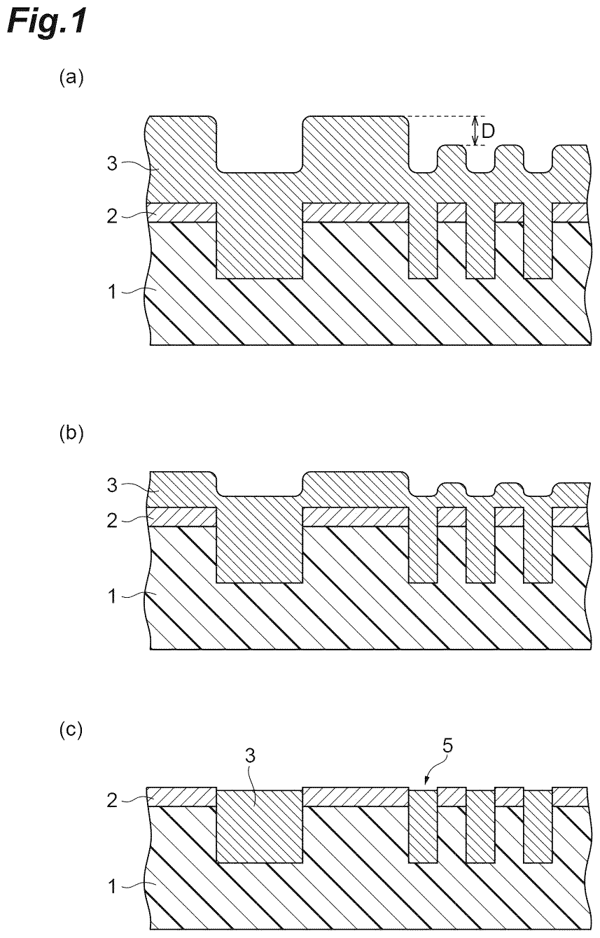

FIG. 1 is a schematic cross-sectional view illustrating a polishing step when forming an STI structure of a semiconductor. FIG. 1(a) is a schematic cross-sectional view illustrating a base before polishing. FIG. 1(b) is a schematic cross-sectional view illustrating the base during polishing. FIG. 1(c) is a schematic cross-sectional view illustrating the base after polishing. As shown in FIG. 1(a), the base includes a substrate (for example, a semiconductor substrate such as a silicon substrate) 1 having a concave-convex pattern, a stopper 2 placed on the convex portion of the substrate 1, and an insulating material 3 placed on the substrate 1 and the stopper 2 so as to fill the concave portion. A step D is formed on the surface of the insulating material 3. As shown in FIG. 1(b), in the polishing process, an unnecessary portion partially protruding from the surface of the insulating material 3 is preferentially removed by CMP, and thus the step D of the insulating material 3 is reduced. During such polishing, the polishing of the insulating material 3 is stopped by the stopper 2 at the stage in which the stopper 2 is exposed as shown in FIG. 1(c), thus forming an STI structure having an embedded portion 5.

In this way, by polishing the insulating material formed on the substrate with the above polishing liquid for CMP to remove excess portions, unevenness on the surface of the insulating material can be eliminated, and by stopping the polishing when the stopper is exposed, excessive polishing of the insulating material is prevented, whereby a smooth surface can be obtained over the entire surface of the insulating material. The polishing liquid for CMP of the present embodiment can be used for polishing a surface to be polished containing a stopper (polysilicon, amorphous silicon, or the like). The polishing liquid for CMP of the present embodiment can be used for polishing a surface to be polished containing at least one of silicon oxide and silicon nitride.

In the polishing method of the present embodiment, a general polishing apparatus including a holder capable of holding a base (for example, a semiconductor substrate) having a surface to be polished and a polishing surface plate to which a polishing pad can be attached can be used as the polishing apparatus. Each of the holder and the polishing surface plate is equipped with a motor of which the rotation number can be changed. As the polishing apparatus, for example, product name: Reflexion which is a polishing apparatus manufactured by Applied Materials, Inc.; and product name F-REX which is a polishing apparatus manufactured by EBARA CORPORATION can be used.

As the polishing pad, a general nonwoven fabric, foam, non-foam, or the like can be used. As the material for the polishing pad, resins such as polyurethane, an acrylic resin, polyester, an acrylic-ester copolymer, polytetrafluoroethylene, polypropylene, polyethylene, poly-4-methylpentene, cellulose, cellulose ester, polyamide (for example, nylon and aramid), polyimide, polyimideamide, a polysiloxane copolymer, an oxirane compound, a phenolic resin, polystyrene, polycarbonate, and an epoxy resin can be used. Particularly, from the viewpoints of the polishing rate and planeness, the material for the polishing pad may be foamed polyurethane or non-foamed polyurethane. The polishing pad may be subjected to groove processing to allow the polishing liquid to accumulate.

Although the polishing conditions are not limited, the rotation rate (rotation number) of the polishing surface plate may be 200 min-1 or less to prevent the base from flying off, and the polishing pressure (processing load) applied to the base may be 100 kPa or less, from the viewpoint of sufficiently suppressing the occurrence of polishing flaws. During the polishing, the polishing liquid may be continuously supplied to the polishing pad by a pump or the like. Although the amount of the polishing liquid supplied is not limited, the surface of the polishing pad may be constantly covered with the polishing liquid.

After the polishing is completed, the base may be thoroughly washed in running water to remove particles adhering to the base. For the washing, other than pure water, chemicals for washing such as diluted hydrofluoric acid and aqueous ammonia may be used, and a brush may be used to improve washing efficiency. Furthermore, after the washing, water droplet adhering to the base may be removed using a spin dryer or the like, and then the base may be dried.

The polishing liquid for CMP, the polishing liquid set for CMP, and the polishing method of the present embodiment can be used in the process of forming an STI and polishing a pre-metal insulating material, an interlayer insulating material, or the like. As the pre-metal insulating material, other than silicon oxide, for example, phosphorus silicate glass, boron-phosphorus-silicate glass, silicon oxyfluoride, amorphous carbon fluoride, or the like can be used.

The polishing liquid for CMP, the polishing liquid set for CMP, and the polishing method of the present embodiment can be applied not only to a film-like object to be polished, but also to various substrates formed of glass, silicon, SiC, SiGe, Ge, GaN, GaP, GaAs, sapphire, plastic, and the like.

The polishing liquid for CMP, the polishing liquid set for CMP, and the polishing method of the present embodiment can be used not only for the production of a semiconductor device but also for production of image display devices such as TFT liquid crystal and organic EL; optical components such as a photomask, a lens, a prism, an optical fiber, and a single crystal scintillator; optical elements such as an optical switching element and optical waveguide; light-emitting elements such as solid-state laser and blue laser LEDs; and magnetic storage devices such as a magnetic disk and a magnetic head.

### <Manufacturing Method and the Like>

A method for producing a component of the present embodiment includes a component producing step of obtaining a component by using a base substrate (polished member) polished by the polishing method of the present embodiment. A component of the present embodiment is a component obtained by the method of producing a component of the present embodiment. The component of the present embodiment is not particularly limited, and may be an electronic component (for example, a semiconductor component such as a semiconductor package), may be a wafer (for example, a semiconductor wafer), and may be a chip (for example, a semiconductor chip). As an embodiment of the method for producing a component of the present embodiment, in a method for producing an electronic component of the present embodiment, an electronic component is obtained by using a base substrate polished by the polishing method of the present embodiment. As an embodiment of the method for producing a component of the present embodiment, in a method for producing a semiconductor component of the present embodiment, a semiconductor component (for example, a semiconductor package) is obtained by using a base substrate polished by the polishing method of the present embodiment. The method for producing a component of the present embodiment may include a polishing step of polishing a base substrate by the polishing method of the present embodiment before the component producing step.

The method for producing a component of the present embodiment may include, as an embodiment of the component producing step, an individually dividing step of dividing a base substrate (polished member) polished by the polishing method of the present embodiment into individual pieces. The individually dividing step may be, for example, a step of dicing a wafer (for example, a semiconductor wafer) polished by the polishing method of the present embodiment to obtain chips (for example, semiconductor chips). As an embodiment of the method for producing a component of the present embodiment, the method for producing an electronic component of the present embodiment may include a step of obtaining an electronic component (for example, a semiconductor component) by individually dividing a base substrate polished by the polishing method of the present embodiment into individual pieces. As an embodiment of the method for producing a component of the present embodiment, the method for producing a semiconductor component of the present embodiment may include a step of obtaining a semiconductor component (for example, a semiconductor package) by individually dividing a base substrate polished by the polishing method of the present embodiment into individual pieces.

The method for producing a component of the present embodiment may include, as an embodiment of the component producing step, a connecting step of connecting (for example, electrically connecting) a base substrate (polished member) polished by the polishing method of the present embodiment to another body to be connected. The body to be connected that is connected to the base substrate polished by the polishing method of the present embodiment is not particularly limited, and may be a base substrate polished by the polishing method of the present embodiment, and may be a body to be connected different from the base substrate polished by the polishing method of the present embodiment. In the connecting step, the base substrate and the body to be connected may be directly connected to each other (connected in a state where the base substrate and the body to be connected are in contact with each other), and the base substrate and the body to be connected may be connected via another member (such as a conductive member). The connecting step can be performed before the individually dividing step, after the individually dividing step, or before and after the individually dividing step.

The connecting step may be a step of connecting a polished surface of a base substrate polished by the polishing method of the present embodiment to a body to be connected, and may be a step of connecting a connection surface of a base substrate polished by the polishing method of the present embodiment to a connection surface of a body to be connected. The connection surface of the base substrate may be a polished surface that is polished by the polishing method of the present embodiment. A connection body having the base substrate and the body to be connected can be obtained by the connecting step. In the connecting step, in a case where the connection surface of the base substrate has a metal portion, the body to be connected may be connected to the metal portion. In the connecting step, in a case where the connection surface of the base substrate has a metal portion and the connection surface of the body to be connected has a metal portion, the metal portions may be connected to each other. The metal portion may contain copper.

A device of the present embodiment (for example, an electronic device such as a semiconductor device) includes at least one selected from the group consisting of a base polished by the polishing method of the present embodiment and the component of the present embodiment.

### Examples

Hereinafter, the present disclosure will be described in more detail based on Examples, but the present disclosure is not limited to these Examples.

### <Synthesis of Particles of Hydroxide of Tetravalent Metal Element>

350 g of 50 mass % aqueous Ce(NH₄)₂(NO₃)₆ solution (manufactured by NIHON KAGAKU SANGYO CO., LTD., product name: CAN50 solution) was dissolved in 7825 g of pure water to obtain a solution. Then, while stirring the solution, 750 g of aqueous imidazole solution (10 mass % aqueous solution) was added dropwise at a rate of 5 mL/min to obtain a precipitate of particles containing cerium hydroxide.

The obtained precipitate containing cerium hydroxide was centrifuged (4000 min⁻¹, for 5 minutes) and then subjected to solid-liquid separation by removing the liquid phase by decantation. Furthermore, 10 g of the obtained particles and 990 g of water were mixed together, and the particles were dispersed in water using an ultrasonic washing machine to prepare a stock solution for a cerium hydroxide slurry (content of particles: 1.0 mass %).

When the average particle size of abrasive grains in the cerium hydroxide slurry (abrasive grains containing cerium hydroxide) was measured using trade name: DelsaMax Pro manufactured by Beckman Coulter, Inc., the average particle size was 8 nm. The measurement method is as follows. First, about 1 mL of a measurement sample (cerium hydroxide slurry, aqueous dispersion) containing 1.0 mass % abrasive grains was placed in a 1 cm² cell, and the cell was placed in DelsaMax Pro. Next, the refractive index and viscosity of the measurement sample information in the DelsaMax Pro software were set to 1.333 and 0.887 mPa·s, respectively, the measurement was performed at 25° C., and the value displayed as Unimodal Size Mean was read.

An appropriate amount of the stock solution for the cerium hydroxide slurry was collected and diluted with water so that the content of the particles was 0.0065 mass %, thus obtaining a measurement sample (aqueous dispersion). About 4 mL of the measurement sample was placed in a 1 cm² cell, and the cell was placed in a spectrophotometer (apparatus name: U3310) manufactured by Hitachi, Ltd. The absorbance was measured in the wavelength range of 200 to 600 nm, and the absorbance for light with a wavelength of 290 nm and the absorbance for light with a wavelength of 450 to 600 nm were measured. The absorbance for the light with the wavelength of 290 nm was 1.192, and the absorbance for the light with the wavelength of 450 to 600 nm was lower than 0.010.

About 4 mL of the stock solution for the cerium hydroxide slurry (content of particles: 1.0 mass %) was placed in a 1 cm² cell, and the cell was placed in a spectrophotometer (apparatus name: U3310) manufactured by Hitachi, Ltd. The absorbance was measured in the wavelength range of 200 to 600 nm, and the absorbance for light with a wavelength of 400 nm and the optical transmittance for light with a wavelength of 500 nm were measured. The absorbance for the light with the wavelength of 400 nm was 2.25, and the optical transmittance for the light with the wavelength of 500 nm was 92%/cm.

Measurement was performed by the FT-IR ATR method on a sample obtained by collecting an appropriate amount of the stock solution for the cerium hydroxide slurry, isolating the abrasive particles by vacuum drying, and sufficiently washing the abrasive particles with pure water. As a result, a peak due to an NO₃ group was observed, in addition to a peak due to an OH group. In addition, when XPS (N-XPS) measurement for nitrogen was performed on the same sample, no peak due to NH₄ was observed, but a peak due to NO₃ was observed. From these results, it was confirmed that at least a portion of the abrasive grains contained in the above stock solution for the cerium hydroxide slurry contained particles having NO₃ groups bonded to the cerium element.

### <Preparation of Polishing Liquid for CMP>

A polishing liquid for CMP used in each of Examples and each of Comparative Examples was prepared so as to contain, based on the total mass of the polishing liquid for CMP, 0.05 mass % cerium hydroxide as abrasive grains, additives described below in the amounts shown in Tables 1 to 4, cationic polymers described below in the amounts shown in Tables 1 to 4, acetic acid in the amounts shown in Tables 1 to 4, aqueous ammonia in the amounts shown in Tables 1 to 4 (solid content), and 0.5 mass % polyglycerol, with the remainder being pure water. The following compounds were used as the additives.

### [Additives]

A1: 1,1′,1″,1″-Ethylenedinitrilotetra-2-propanol
A2: 2,2′,2″,2″-Ethylenedinitrilotetraethanol
A3: N-(2-hydroxypropyl)ethylenediamine
A4: Ethylenediaminetetrapolyoxyalkylene (weight-average molecular weight of 6000; polyoxyalkylene chain has a hydroxy group at the end; ratio of polyoxypropylene chains to polyoxyethylene chains (PO chains/EO chains): 65/35)
A5: Tetramethylethylenediamine
A6: Monoethanolamine
A7: 3-Amino-1-propanol

### [Cationic Polymer]

B1: Diallyldimethylammonium chloride-acrylamide copolymer
B2: Dimethylamine-ammonia-epichlorohydrin polycondensate
B3: Diallylamine hydrochloride-acrylamide copolymer
B4: Methyldiallylamine hydrochloride-epichlorohydrin modified polymer
B5: Vinylpyrrolidone-N,N-dimethylaminoethyl methacrylic acid copolymer diethyl sulfate

Specifically, the above stock solution for the cerium hydroxide slurry was diluted 5 to 10 times with water to obtain a slurry that contained particles containing cerium hydroxide as abrasive grains. Next, each of the components other than the abrasive grains was dissolved in pure water, thus obtaining an additive liquid. Next, the above slurry and the above additive liquid were mixed together and stirred, thus preparing the polishing liquid for CMP. The average particle size of the abrasive grains in the polishing liquid for CMP of each Example, which was measured by the same method as that for the average particle size of the abrasive grains in the above slurry, was equal to the average particle size of the abrasive grains in the above slurry.

### <pH Measurement>

The pH of the polishing liquid for CMP was measured under the following conditions. The results are shown in each table.
Measurement temperature: 25° C.
Measurement device: Trade name: Model (D-71) of HORIBA, Ltd.
Measurement method: The pH meter was subjected to three-point calibration using, as pH standard solutions, a phthalate pH standard solution (pH: 4.01), a neutral phosphate pH standard solution (pH: 6.86), and a borate pH standard solution (pH: 9.18), and then the electrode of the pH meter was placed in the polishing liquid for CMP. After stabilizing for more than 2 min, the pH was measured using the above measurement device. The pHs of the polishing liquids for CMP are shown in Tables 1 and 2.

### <Evaluation of Polishing Properties>

A film to be polished (silicon oxide film (TEOS film), silicon nitride film (SiN film), polysilicon film (p-Si film), or amorphous silicon film (a-Si film)) formed on a silicon substrate was polished under the following CMP polishing conditions using the polishing liquid for CMP of each of Examples and each of Comparative Examples. (CMP polishing conditions)
Polishing apparatus: F-REX300X (manufactured by EBARA CORPORATION)
Flow rate of polishing liquid for CMP: 200 mL/min
Polishing pad: Closed-cell foamed polyurethane resin (manufactured by Rohm and Haas Japan K.K., model number: IC1000)
Polishing pressure: 14.7 kPa (2 psi)
Rotation number of surface plate: 93 rpm
Rotation number of head: 87 rpm
Polishing time: 30 seconds
Washing: After CMP treatment, washing was performed with water, and then drying was performed with a spin dryer.

### (Evaluation Items for Polished Product)

The polishing rate of the film to be polished (silicon oxide film, silicon nitride film, polysilicon film, or amorphous silicon film) that had been subjected to polishing and washing under the above conditions was obtained from the following equation. The difference in the thickness of the film to be polished before and after the polishing was obtained using an optical interference-type film thickness measurement device (manufactured by Filmetrics, trade name: F80). The polishing rate of each of the silicon oxide film, silicon nitride film, polysilicon film, and amorphous silicon film is shown in Tables 1 and 2. The cases in which the polishing rate is more than 0 nm/min and less than 1 nm/min are indicated as “<1” in the tables.

$$( Polishing rate ) = ( Difference in thickness of silicon oxide film , silicon nitride film , polysilicon film , \\ or amorphous silicon film before and after polishing ( nm ) ) \times ( 60 / ( polishing time ) ( / min ) )$$

TABLE 1

| | | Example | | | | | | |
|---|---|---|---|---|---|---|---|---|
| | | 1 | 2 | 3 | 4 | 5 | 6 | 7 |
| Additive A | Type | A1 | | | | A2 | A3 | A4 |
| | Content (mass %) | 0.04 | 0.08 | 0.02 | 0.12 | 0.04 | 0.04 | 0.02 |
| Cationic polymer | Type | B1 | | | | | | |
| | Content (mass %) | 0.003 | 0.003 | 0.003 | 0.003 | 0.003 | 0.003 | 0.003 |
| Acetic acid | Content (mass %) | 0.016 | 0.016 | 0.016 | 0.022 | 0.016 | 0.016 | 0.016 |
| Ammonia | Content (mass %) | 0.0030 | 0.0002 | 0.0054 | — | — | — | — |
| pH | | 7.0 | 7.0 | 7.0 | 7.0 | 7.0 | 7.0 | 7.0 |
| Polishing rate | TEOS | 283 | 271 | 291 | 282 | 280 | 270 | 251 |
| (nm/min) | SiN | 61 | 61 | 58 | 54 | 55 | 53 | 33 |
| | p-Si | 2 | 3 | 3 | 31 | 4 | <1 | 0 |
| | a-Si | <1 | 0 | <1 | 1 | <1 | <1 | <1 |

TABLE 2

| | | Example | | | | |
|---|---|---|---|---|---|---|
| | | 8 | 9 | 10 | 11 | 12 |
| Additive | Type | A1 | | | | |
| | Content (mass %) | 0.04 | 0.04 | 0.04 | 0.04 | 0.04 |
| Cationic polymer | Type | B1 | | | | |
| | Content (mass %) | 0.003 | 0.003 | 0.0015 | 0.0045 | 0.006 |
| Acetic acid | Content (mass %) | 0.016 | 0.016 | 0.016 | 0.016 | 0.016 |
| Ammonia | Content (mass %) | 0.0024 | 0.0043 | 0.0030 | 0.0032 | 0.0032 |
| pH | | 8.0 | 6.1 | 7.0 | 7.0 | 7.0 |
| Polishing rate | TEOS | 291 | 264 | 234 | 363 | 421 |
| (nm/min) | SiN | 53 | 34 | 52 | 39 | 39 |
| | p-Si | 3 | 4 | 28 | 9 | 26 |
| | a-Si | 1 | <1 | 2 | <1 | 0 |

TABLE 3

| | | Example | | | |
|---|---|---|---|---|---|
| | | 13 | 14 | 15 | 16 |
| Additive | Type | A1 | | | |
| | Content (mass %) | 0.04 | 0.04 | 0.04 | 0.04 |
| Cationic polymer | Type | B2 | B3 | B4 | B5 |
| | Content (mass %) | 0.003 | 0.003 | 0.003 | 0.003 |
| Acetic acid | Content (mass %) | 0.016 | 0.016 | 0.016 | 0.016 |
| Ammonia | Content (mass %) | 0.0034 | 0.0031 | 0.0031 | 0.0032 |
| pH | | 7.0 | 7.0 | 7.0 | 7.0 |
| Polishing rate | TEOS | 314 | 280 | 233 | 142 |
| (nm/min) | SiN | 43 | 50 | 48 | 52 |
| | p-Si | 6 | 7 | 4 | 11 |
| | a-Si | <1 | 0 | <1 | <1 |

TABLE 4

| | | Comparative Example | | | | |
|---|---|---|---|---|---|---|
| | | 1 | 2 | 3 | 4 | 5 |
| Additive | Type | — | A1 | A5 | A6 | A7 |
| | Content (mass %) | — | 0.04 | 0.04 | 0.04 | 0.02 |
| Cationic polymer | Type | B1 | | | | |
| | Content (mass %) | — | — | 0.003 | 0.003 | 0.003 |
| Acetic acid | Content (mass %) | 0.016 | 0.016 | 0.016 | 0.016 | 0.016 |
| Ammonia | Content (mass %) | 0.0054 | 0.0031 | — | — | 0.0008 |
| pH | | 7.0 | 7.0 | 8.1 | 7.7 | 7.0 |
| Polishing rate | TEOS | 7 | 114 | 21 | 289 | 277 |
| (nm/min) | SiN | 55 | 60 | 31 | 42 | 46 |
| | p-Si | 30 | 33 | 18 | 74 | 48 |
| | a-Si | 2 | 6 | <1 | 5 | 7 |

### REFERENCE SIGNS LIST

1 Substrate
2 Stopper
3 Insulating material
5 Embedded portion
D Step

1. A polishing liquid for CMP, comprising: abrasive grains; an additive A; a cationic polymer; and water,
wherein the additive A comprises a compound having an ethylenediamine structure bonded to a hydroxyalkyl group or an alkoxide group.

2. The polishing liquid for CMP according to claim 1, wherein the abrasive grains comprise at least one selected from the group consisting of cerium hydroxide, ceria, silica, and alumina.

3. The polishing liquid for CMP according to claim 1, wherein the abrasive grains comprise cerium hydroxide.

4. The polishing liquid for CMP according to claim 1, wherein the additive A comprises 2,2′,2″,2′″-ethylenedinitrilotetraethanol.

5. The polishing liquid for CMP according to claim 1, wherein the additive A comprises 1,1′,1″,1′″-ethylenedinitrilotetra-2-propanol.

6. The polishing liquid for CMP according to claim 1, wherein a content of the additive A is 0.001 to 5 mass %.

7. The polishing liquid for CMP according to claim 1, wherein the cationic polymer comprises a polymer having a quaternary ammonium salt structure or a polymer having an amino group.

8. The polishing liquid for CMP according to claim 1, wherein a content of the cationic polymer is 2 to 20 parts by mass with respect to 100 parts by mass of the additive A.

9. The polishing liquid for CMP according to claim 1, further comprising polyether.

10. The polishing liquid for CMP according to claim 1, wherein pH is 4.0 to 10.0.

11. The polishing liquid for CMP according to claim 1, wherein pH is higher than 6.0 and lower than 9.0.

12. The polishing liquid for CMP according to claim 1 is used for polishing a surface to be polished comprising silicon oxide, silicon nitride, polysilicon, and amorphous silicon.

13. A polishing liquid set for CMP, comprising: a first liquid; and a second liquid, wherein components of the polishing liquid for CMP according to claim 1 are separately stored in the first liquid and the second liquid, the first liquid comprises the abrasive grains and water, and the second liquid comprises the additive A, the cationic polymer, and water.

14. A polishing method comprising a step of polishing a surface to be polished by using the polishing liquid for CMP according to claim 1.

15. The polishing method according to claim 14, wherein the surface to be polished comprises silicon oxide, silicon nitride, polysilicon, and amorphous silicon.

16. A polishing method comprising a step of polishing a surface to be polished by using a polishing liquid for CMP obtained by mixing the first liquid and the second liquid of the polishing liquid set for CMP according to claim 13.

17. The polishing method according to claim 16, wherein the surface to be polished comprises silicon oxide, silicon nitride, polysilicon, and amorphous silicon.
